(19) United States
(12) Patent Application Publication
(10) Pub. No.: US 2002/0179927 A1
(43) Pub. Date: Dec. 5, 2002

(54) Thin film transistor and method for manufacturing the same

(75) Inventors: I-Min Lu, Taipei (TW); Jr-Hong Chen, Taipei Hsien (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 10/200,187

(22) Filed: Jul. 23, 2002

Related U.S. Application Data
(62) Division of application No. 09/864,192, filed on May 25, 2001.

(30) Foreign Application Priority Data
Dec. 15, 2000 (TW) 89126879

(51) Int. Cl. H01L 21/84; H01L 29/74

(52) U.S. Cl. 257/151; 438/151

(57) ABSTRACT

A thin film transistor having an improved reliability and a method of manufacturing the same are provided, which can produce a high quality thin film transistor device and array. The manufacturing method includes the steps of: forming a poly-Si island on a substrate; depositing a silicon oxide layer to cover the substrate and the poly-Si island, and then depositing a silicon nitride layer on the silicon oxide layer; forming a metal layer on the silicon nitride layer, and then patterning the metal layer to form a gate; using the gate as a mask and etching the silicon nitride layer to remove a portion of the silicon nitride layer, which is not covered by the gate; forming source/drain regions in the poly-Si layer on both sides of the gate, and then depositing an interlayer to cover the silicon oxide layer and the gate; and forming contact holes in the interlayer and the silicon oxide layer above the source/drain regions, and then filling conductive plugs in the contact holes. The thin film transistor is characterized in that a silicon nitride layer is formed on the silicon oxide layer before forming the gate metal in the manufacturing process. The silicon oxide layer and the silicon nitride layer are combined to serve as the gate insulator, which can facilitate integration through the oxide doping process. Moreover, the defect in the poly-Si layer can be eliminated by performing the hydrogenation process to improve the current-voltage characteristic of the transistor.

This application is a divisional of co-pending application Ser. No. 09/864,192, filed on May 25, 2001, the entire contents of which are hereby incorporated by reference and for which priority is claimed under 35 U.S.C. §120; and this application claims priority of Application No. 89126879 filed in Taiwan, R.O.C. on Dec. 15, 2000 under 35 U.S.C. §119.

### BACKGROUND OF THE INVENTION

1. Field of the Invention

The present invention relates to a semiconductor device, especially to a thin film transistor having an improved reliability and a method for manufacturing the same.

2. Description of the Related Art

Conventionally, TFT (Thin-Film Transistor) LCD is mostly used to display images. There are two kinds of common TFTs, i.e., a-Si:H TFT and poly-Si TFT. A-Si:H TFT is cheaper and the extra large area technique of such a TFT is matured. However, a-Si:H TFT has a slow speed and a high sensitivity to heat and light, thus the reliability of a-Si:H TFT is not good. On the contrary, poly-Si TFT has a fast speed and is stable while working. Therefore, poly-Si TFT is applied to high-resolution display.

Referring to FIGS. 1A to 1F, the conventional method of manufacturing a poly-Si TFT includes the steps of: (i) step 100, as shown in FIG. 1A, depositing a layer of poly-Si 12 on the substrate 10; (ii) step 110, as shown in FIG. 1B, depositing an oxide layer 14 on the poly-Si layer 12, then depositing a metal layer on the oxide layer 14, and patterning the metal layer to form a gate 16; (iii) step 120, as shown in FIG. 1C, implanting the poly-Si layer 12 uncovered by the gate 16 to respectively form a source/drain region 18; (iv) step 130, as shown in FIG. 1D, forming a dielectric layer 20 on the oxide layer 14 and the gate 16, and forming contact holes 22 on the source/drain region 18 by etching; (v) step 140, as shown in FIG. 1E, filling conductive plug 24 in the contact holes 22 to connect the source/drain region 18 to other circuits; (vi) step 150, as shown in FIG. 1F, forming a passivation layer to cover the whole structure.

As the demand on the resolution of TFT LCD panel increases, a possible way to meet this requirement is to reduce the thickness of the gate oxide of poly-Si TFT, so as to reduce the required driving voltage and improve the characteristics of the panel. However, the reliability of the TFT device deteriorates if the gate oxide is too thin.

### SUMMARY OF THE INVENTION

Accordingly, to overcome the drawbacks of the prior art, an object of this invention is to provide a thin film transistor and the manufacturing method of the same, which is mostly applied to poly-Si TFT to improve the reliability.

In the manufacturing method of this invention, SiNₓ/SiOₓ is deposited on the poly-Si island and the substrate before forming the gate metal to serve as a gate insulator.

High quality TFT and its array can be obtained by adopting the manufacturing method and the structure of this invention. Furthermore, the silicon oxide of this invention is thinner than that of the prior art. This facilitates integration through the oxide doping process. The defect in the poly-Si layer can be eliminated by performing the hydrogenation process with the use of the silicon nitride formed on the silicon oxide to improve the current-voltage characteristics of the transistor.

### BRIEF DESCRIPTION OF THE DRAWINGS

The present invention can be more fully understood by reading the subsequent detailed description in conjunction with the examples and references made to the accompanying drawings, wherein:

FIGS. 1A to 1F are cross-sectional diagrams illustrating the manufacturing process of a conventional TFT;

FIGS. 2A to 2F are cross-sectional diagrams illustrating the manufacturing process of the TFT having an improved reliability according to this invention.

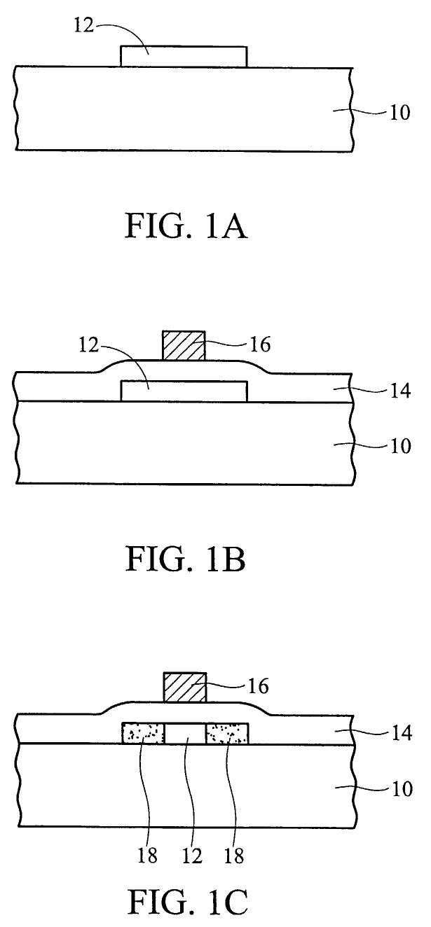

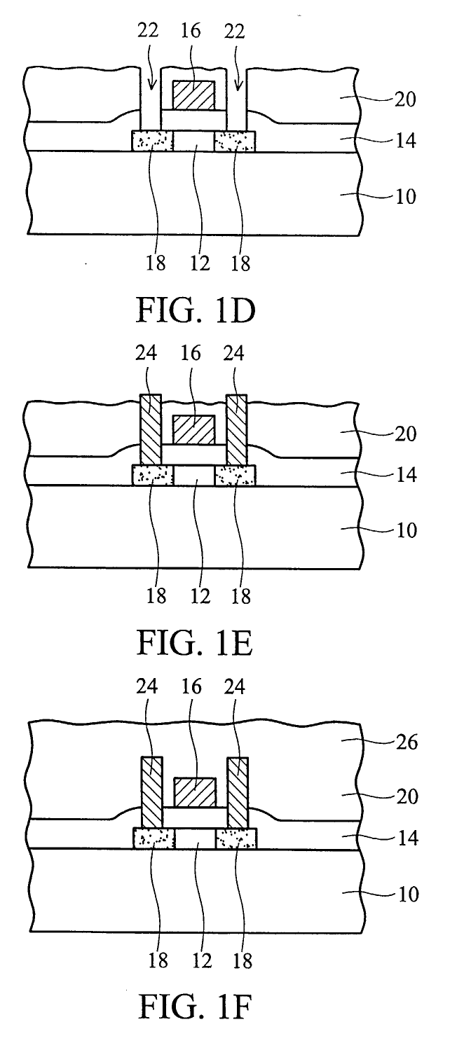

### DETAILED DESCRIPTION OF THE PREFERRED EMBODIMENT

According to one embodiment of this invention, the manufacturing process of the TFT having an improved reliability is depicted below.

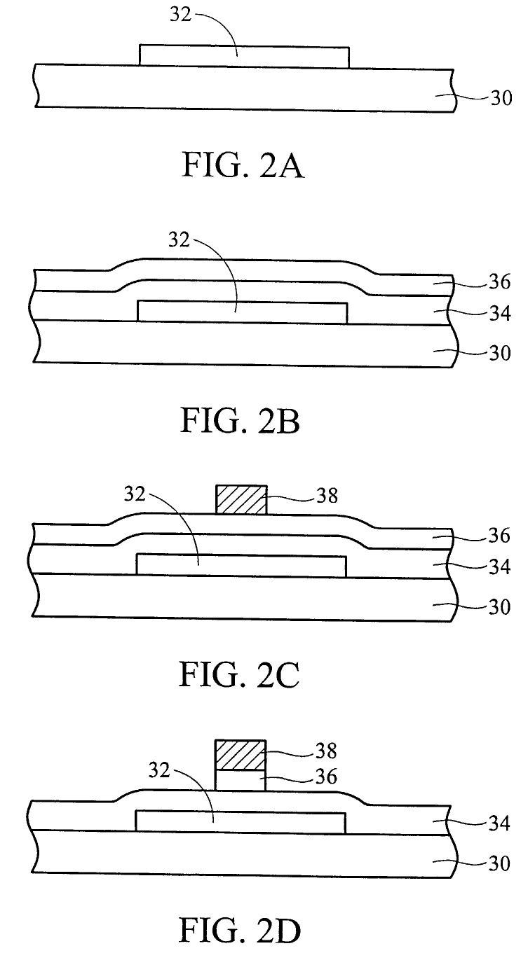

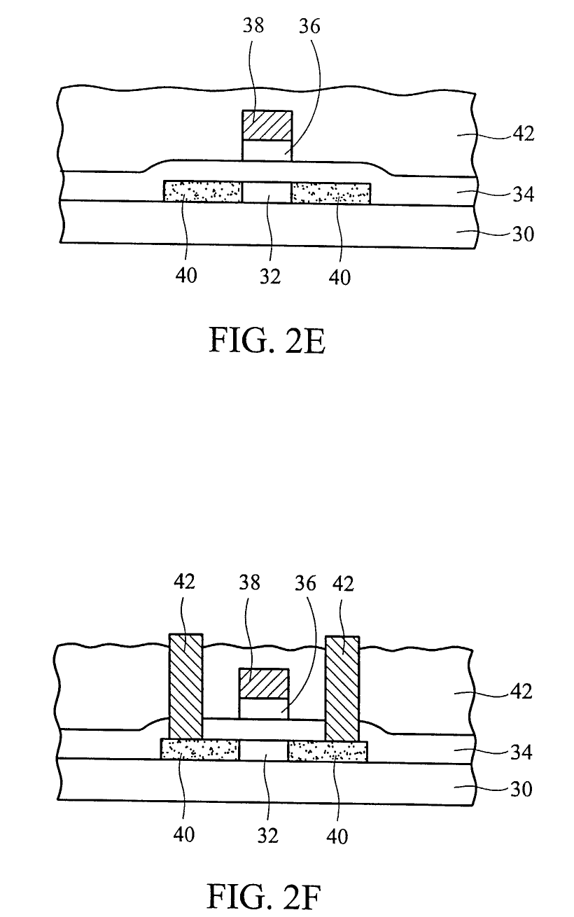

Referring to FIG. 2A, a poly-Si layer, which has a thickness of about 500Å, is formed on the glass substrate 30. The poly-Si layer is formed as a poly-Si island 32 by photolithography and etching.

Referring to FIG. 2B, a layer of tertraethylorthosilicate (TEOS) 34, which has a thickness of about 500Å, is formed to cover the glass substrate 30 and the poly-Si island 32. A layer of SiNₓ 36 having a thickness of around 500Å is then formed on the TEOS layer 34. The TEOS layer 34 and the SiNₓ layer 36 are served as a gate insulator. The thickness of the TEOS layer 34 and the SiNₓ layer 36 is substantially equal to that of a prior-art gate insulator.

Referring to FIG. 2C, a metal layer such as MoW, which has a thickness of about 3000Å, is formed on the SiNₓ layer 36. The metal layer is then patterned to form a gate 38 by photolithography and etching.

Referring to FIG. 2D, the gate 38 is used as a mask, then the SiNₓ layer 36 is etched to remove the SiNₓ layer that is not covered by the gate 38.

Referring to FIG. 2E, the source/drain regions 40 are formed in the poly-Si layer 32 on both sides of the gate 38 by self-aligned ion implantation. Thereafter, an interlayer 42 such as TEOS having a thickness of about 3000Å is deposited on the SiOₓ layer 44 and the gate 38.

Referring to FIG. 2F, contact holes are formed in the interlayer 42 and the SiOₓ layer 34 above the source/drain regions 40 by photolithography and etching. Conductive plugs 44 are filled in the contact holes. The conductive plug can be MoW, which has a thickness of about 3000Å. A passivation layer such as TEOS, which has a thickness of 30000Å, is then deposited to cover the whole structure.

This invention is characterized in that a SiNₓ layer is formed on the SiOₓ layer before forming the gate metal in the manufacturing process. Thus, since the dielectric constant of SiNₓ is relatively large, the gate insulator can be formed thinner in this invention than in prior art if the capacitance Cst and the area of the equivalent capacitance are fixed. Moreover, the area of the equivalent capacitance can be formed smaller in this invention to increase the aperture ratio if the capacitance Cst and the thickness of the gate insulator are fixed.

Referring to FIG. 2F again, the thin film transistor that can improve the reliability of the device includes: a substrate 30; a poly-Si layer 32 formed on the substrate 30; a silicon oxide layer 34 formed to cover the poly-Si layer 32 and the substrate 30; a silicon nitride layer 36 formed on the silicon oxide layer 34 and defined on the region to form gate; a gate 38 formed on the silicon nitride 36; source/drain 40 formed in the poly-Si layer on the both sides of the gate 38; an interlayer 42 formed to cover the above-described structure; contact holes formed in the interlayer 42 and the silicon oxide 34 above the source/drain 40, respectively; and conductive plugs 44 formed in the contact holes to connect the source/drain 40 to other circuits.

Finally, while the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. The method for manufacturing a thin film transistor having an improved reliability, comprising the steps of:
(i) forming a poly-Si island on a substrate;
(ii) depositing a silicon oxide layer to cover the substrate and the poly-Si island, and then depositing a silicon nitride layer on the silicon oxide layer;
(iii) forming a metal layer on the silicon nitride layer, and then patterning the metal layer to form a gate;
(iv) using the gate as a mask and etching the silicon nitride layer to remove a portion of the silicon nitride layer, which is not covered by the gate;
(v) forming source/drain regions in the poly-Si layer on both sides of the gate, and then depositing an interlayer to cover the silicon oxide layer and the gate; and
(vi) forming contact holes in the interlayer and the silicon oxide layer above the source/drain regions, and then filling conductive plugs in the contact holes.

2. The manufacturing method as claimed in claim 1, wherein the silicon oxide layer is TEOS having a thickness of about 500Å.

3. The manufacturing method as claimed in claim 1, wherein the silicon nitride layer has a thickness of about 500Å.

4. The manufacturing method as claimed in claim 1, wherein the gate has a thickness of about 3000Å.

5. The manufacturing method as claimed in claim 1, wherein the interlayer is TEOS having a thickness of about 3000Å.

6. The manufacturing method as claimed in claim 1, wherein the conductive plug is made of a metal, which has a thickness of 3000Å.

7. The manufacturing method as claimed in claim 1, wherein the thickness of the silicon oxide layer is substantially equal to that of the silicon nitride layer.
